(19) United States
(12) Patent Application Publication
(10) Pub. No.: US 2003/0080723 A1
(43) Pub. Date: May 1, 2003

(54) Average current estimation scheme for switching mode power supplies

(76) Inventors: Qing Chen, Plano, TX (US); Jin He, Plano, TX (US); Del Ray Hilburn, Mesquite, TX (US); Victor Ke-Ji Lee, Plano, TX (US)

Correspondence Address: CARSTENS YEE & CAHOON, LLP, P O BOX 802334, DALLAS, TX, 75380

(21) Appl. No.: 10/091,788

(22) Filed: Mar. 6, 2002

Related U.S. Application Data
(60) Provisional application No. 60/334,849, filed on Oct. 31, 2001.

(51) Int. Cl. G01R 23/165

(52) U.S. Cl. 324/76.29

(57) ABSTRACT

Compared with the prior art, the invention offers several extra benefits in addition to providing a dc current signal from a sensed peak current signal. First, the control switch is referenced to the ground, and therefore floating drive for the series switch in the prior art is not necessary. Second, the peak current signal is always available regardless of the status of the control switch. By separating the peak and average current signals, the converter can be better controlled and both peak current mode control and current sharing control can be optimized. Finally, referencing the peak current and average current signals to the different grounds provides freedom to implement different control schemes.

### RELATED APPLICATIONS

The present invention is based on Provisional Serial No. 60/334,849 filed on Oct. 31, 2001. The content of this application is incorporated herein by reference.

### FIELD OF THE INVENTION

This invention relates to switching mode power supplies (SMPS) and their control and in particular to a means of accurately measuring the output current being delivered to a load. The power supply has a dc current estimation circuit that extracts dc current information from a measured peak current signal.

### BACKGROUND OF THE INVENTION

In a dc/dc converter, the output current is often needed in many applications, such as current sharing control, current monitoring, etc. The most frequently used method of obtaining dc output current is to use a current sensing resistor, or current shunt, at the output of the dc/dc converter. The problems associated with the current shunt are two fold. First, a current shunt in the output current path will generate a significant power loss, especially for low output voltage dc/dc converters. Second, to extract usable information from the sensed current signal from a noisy environment, a differential amplifier is often needed to pick up the signal and convert it to a proper level, thus increasing the circuit complexity. Therefore, what is needed in the art is a low loss and simple method of estimating dc output current for a dc/dc converter.

FIG. 1 illustrates a prior art circuit that can be used to obtain the dc output current by sensing the switch current, through either a current shunt or a current sensing transformer. U.S. Pat. No. 5,457,620 to Dromgoole provides a general explanation of this circuit. An input voltage 102 is supplied to the power transformer 106. The power transformer 106 has a primary winding 108 and a secondary winding 110. The sensed current signal, which is the voltage 123 across the current shunt 124 is supplied to a load switch 126 in series with a low pass filter made of a resistor 128 and a capacitor 130. The switch 126 is controlled by the same signal driving the power stage switch 122. When the current signal is sensed by the current shunt or the current sensing transformer, the switch is on and the sensed current signal is let through the low pass filter. The low pass filter helps convert that pulsed signal into the dc current signal. When the power stage switch is off and the current signal is zero, the switch is turned off and the low pass filter holds the sensed current signal till next switch cycle commences.

Although this is a very simple dc current estimation circuit and works reasonably well for many applications, it does have its drawback. The control switch is a floating drive, i.e., the control voltage is not referenced to the gate and the source if a MOSFET is used to implement the current estimation switch. The drive signal becomes part of the current sensing signal, introducing extra error in the estimated current signal. To eliminate the error, some kind of floating drive circuit is needed, either a gate drive transformer or a high side driver, which will in turn complicate the overall circuit.

### SUMMARY OF THE INVENTION

The present invention relates to a switching mode power supply and more specifically to an average current estimation circuit that can be used to provide a signal that is proportional to the output current based on a sensed peak current signal by using either a current shunt or a current sensing transformer. In each embodiment, there is a diode through which the peak current signal is fed to a control switch in series with a resistor. A RC filter is in parallel with the series combination of the switch and the resistor.

Compared with the prior art, the invention offers several extra benefits in addition to provide a dc current signal from a sensed peak current. First, a control switch is referenced to the ground, and therefore provides better current estimation accuracy. No extra error is introduced even without the use of a floating drive as shown in the prior art. Next, the peak current signal is always available regardless of the status of the control switch. By separating the peak and average current signals, the converter can be better controlled and both peak current mode control and current sharing control can be optimized. Last, referencing the peak current and average current signals to the different grounds provides freedom to implement different control schemes.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 is a schematic of a prior art of the average current estimation circuit for a switch mode power supply using Dromgools patent;

FIG. 2 shows the basic circuit that estimates dc output current through sensing the power stage switch current;

FIG. 3 illustrates the dc output current estimation circuit when using a current shunt to sense the switch current;

FIGS. 4 and 5 illustrate the dc output current estimation circuit when using a current sensing transformer to sense the switch current;

FIG. 6 shows the dc output current estimation circuit when peak current signal and average current signal are referenced to different grounds; and

FIG. 7 illustrates the use of an op-amp and diode circuit for temperature compensation for the sensed dc current signal.

### DETAILED DESCRIPTION OF THE DRAWINGS

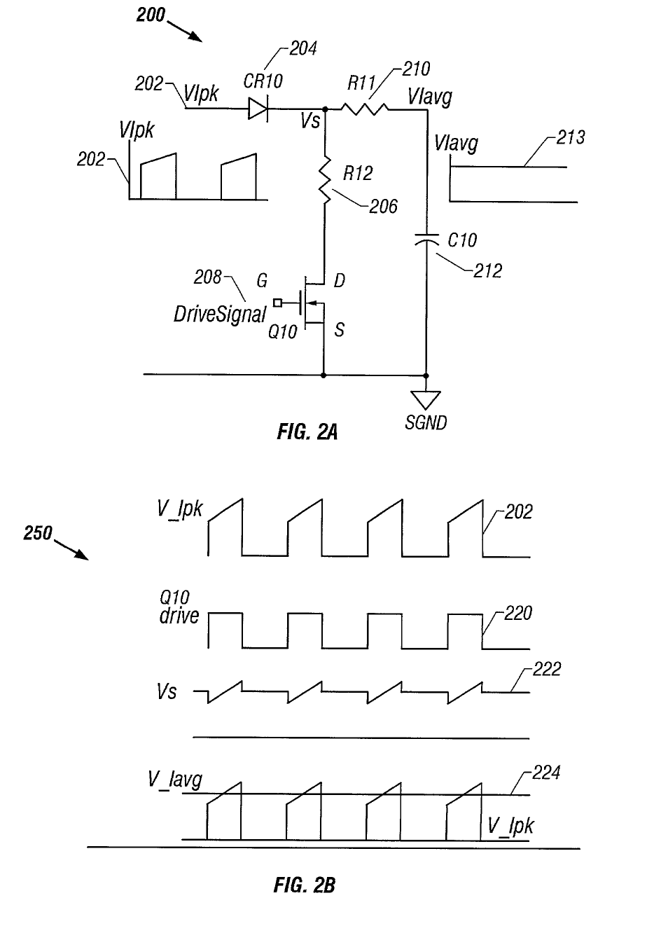

FIG. 2 illustrates a basic circuit 200 that estimates dc output current through sensing the power stage switch current. The basic circuit consists of a diode 204, a resistor 206 in series with a switch 208, another resistor 210 and a capacitor 212. When the sensed peak current 202 is applied to the circuit, the switch 208 turns on. The voltage across the resistor 206 and switch 208, designated V_{S}, is the sensed peak current V_{Ipk} less a forward diode voltage drop. Resistor 210 and capacitor 212 form a low pass filter which filters out the voltage ripple of V_{S} and generates a smooth dc voltage 213 whose value corresponds to the output dc current and is independent of the input voltage provided the magnetizing current of the power transformer is neglected. The diode 204 lets the sensed switch current signal through but prevents the voltage V_{S} as well as V_{Iavg} from being discharged. The switch 208 is a control switch to adjust the sensed dc current signal to reflect the real dc output current. If the load current is decreased, for example, the in-coming current sensing signal is lower than the sensed dc current signal V_{Iavg}. As a result, V_{Iavg} will be discharged during turn-on of switch 208 through resistors 210 and 206, and switch 208, being brought down to the level corresponding to the level of the new dc output current.

For this basic implementation and other circuits described below, a timing diagram is also provided showing the voltage waveforms at different points in the circuit. For example, timing diagram 250 shows the sensed peak current signal that is a pulsed voltage V_{Ipk.} 202. Switch 208 has a duty cycle as shown by waveform 220. The voltage across switch 208 and resistor 206, V_{S}, is shown by waveform 222. And V_{IAVG}, the dc voltage signal that is indicative of the output current seen by the load, is shown with waveform 224. Waveforms 202, 220, 222, and 224 are identical for all embodiments. Further, in each embodiment, the basic circuit 200 will be outlined.

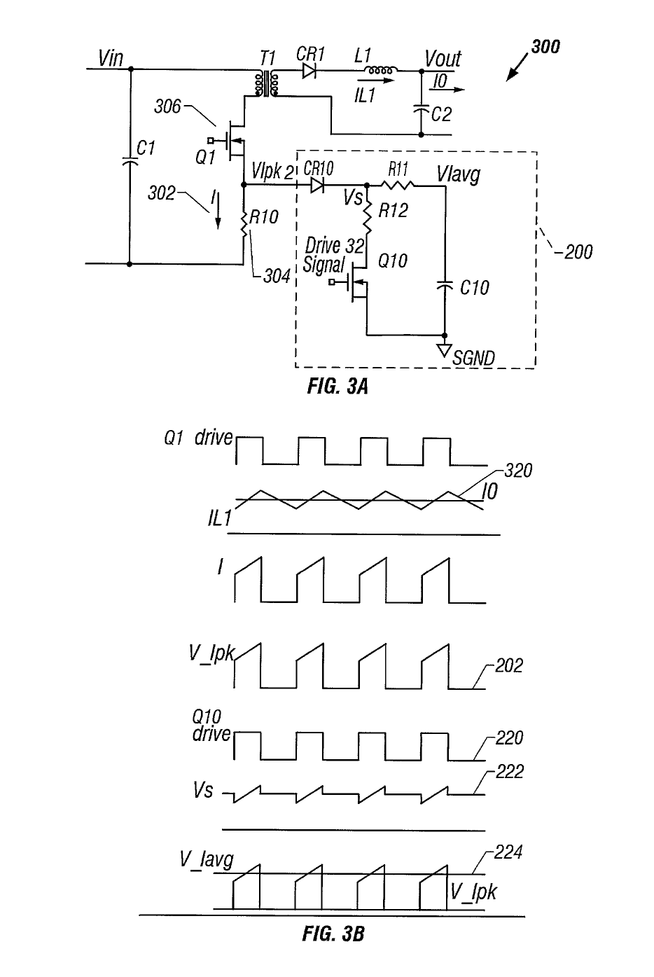

With the basic estimation circuit defined, we can apply this circuit to various topologies to implement dc output current estimation. The first circuit discussed here is a forward converter 300 using a resistor to sense the primary switch current I 302, as shown in FIG. 3. The average current sensing circuit 200 is directly connected to the current sensing resistor 304. During on time of the primary switch 306 the primary switch current I is the reflected secondary output inductor current I_{L1}. The current generates a voltage signal V_{Ipk} across the current shunt resistor 304, which is fed to the average current estimation circuit 200. At the junction of diode 204, resistor 210, and resistor 206 a dc signal V_{S} is obtained which has a small ripple superimposed unto. This ripple is shown in the timing diagram with waveform 320. Note that switch 208 is synchronized with switch 306. After the low pass filter, a smooth voltage V_{Iavg} is obtained across the capacitor 212.

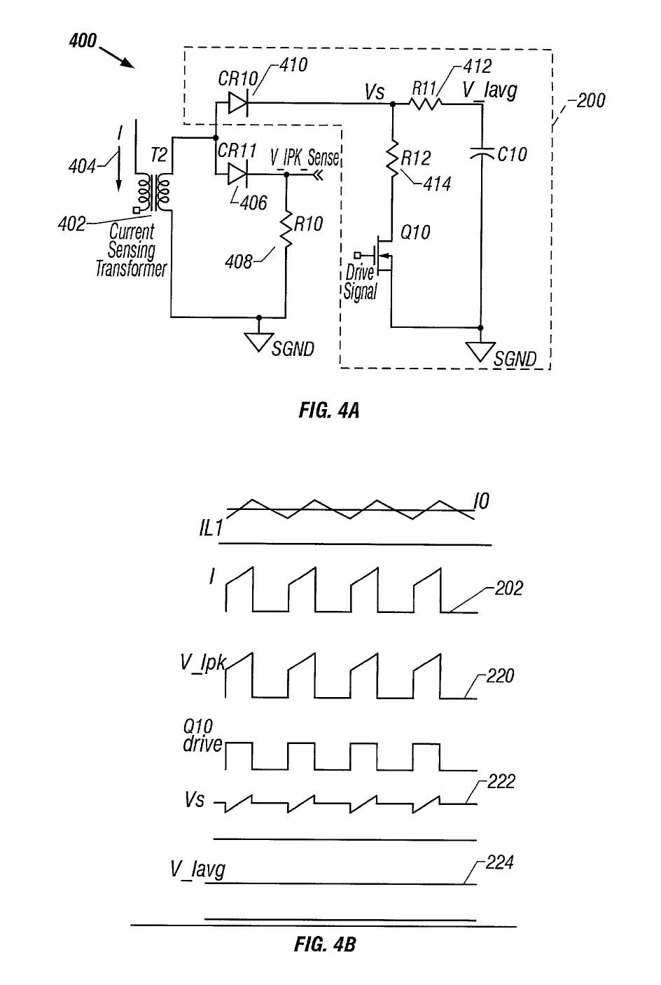

Now turn attention to the same forward circuit 400 with a current sensing transformer 402 as shown in FIG. 4. Since it is identical to that given in FIG. 3, the power stage is not shown in FIG. 4. Now the primary switch current I 404, which is the reflected output inductor current I_{L1} during the on time, flows through the current sensing transformer 402. This current is reflected on the secondary side of the current sensing transformer, part of which flows through diode 406 generating the sensed switch current signal across the burden resistor 408 while the rest of which flows through diode 410 generating V_{S}. Assuming the same voltage drop on the diodes 406 and 410, V_{S} is equal to V_{Ipk}. Again the sensed signal V_{S} is filtered by the low pass filter, generating a smooth dc current signal V_{Iavg}. Examining the circuit given in FIG. 4 carefully, it can be seen that the circuit branches containing diode 406 and diode 410 form a current divider, thus the final sensed signals depend on the resistor values of 408, 412, 414, and V_{CR10} and V_{CR11}. To simplify circuit design while maintaining one-to-one mapping relationships between the switch current and the sensed V_{Ipk} as well as between the dc output current and sensed V_{Iavg}, the circuit can be designed such that the values of resistor 412>resistor 414>>resistor 408. The peak current sensing and dc output current sensing are no longer coupled by separating the resistor values this way. In addition, one can choose diode 406 and diode 410 being the same type diode, better yet physically in the same package, and thus the forward voltage drop variations caused by temperature change will increase or decrease in the same direction, thereby eliminating the temperature effect.

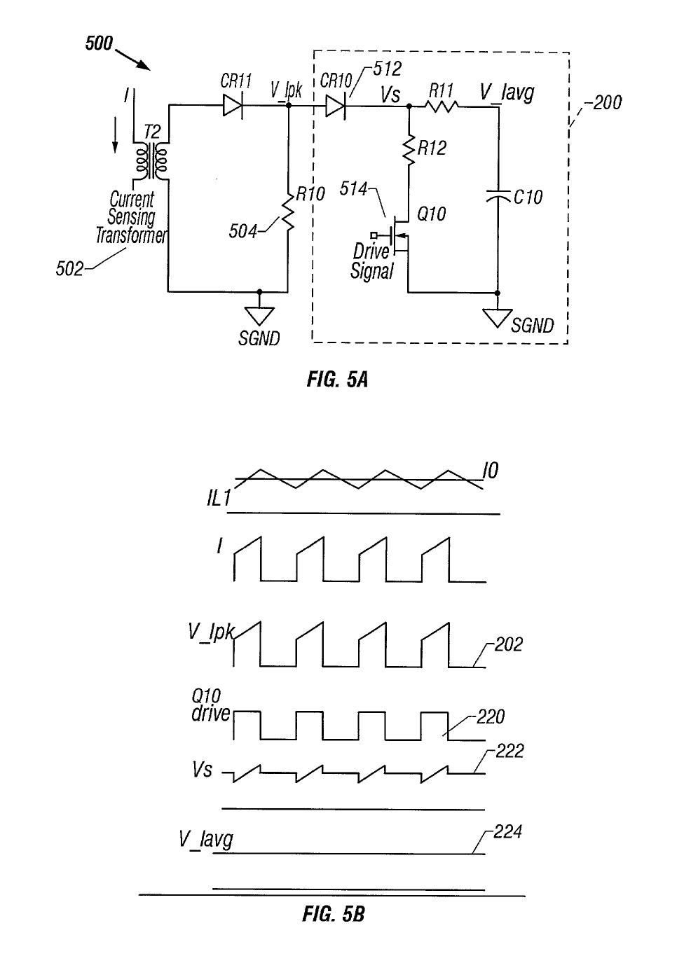

FIG. 5 shows another embodiment of the average current estimation circuit 500 when a current sensing transformer 502 is used. Now the average current estimation circuit is connected to the burden resistor 504, and the V_{Ipk} signal is directly fed to the diode 512 yielding a dc output current signal. The control of the switch 514 is identical to that in FIG. 4, and the result is the same except that V_{S} is one diode voltage drop lower than V_{Ipk} signal.

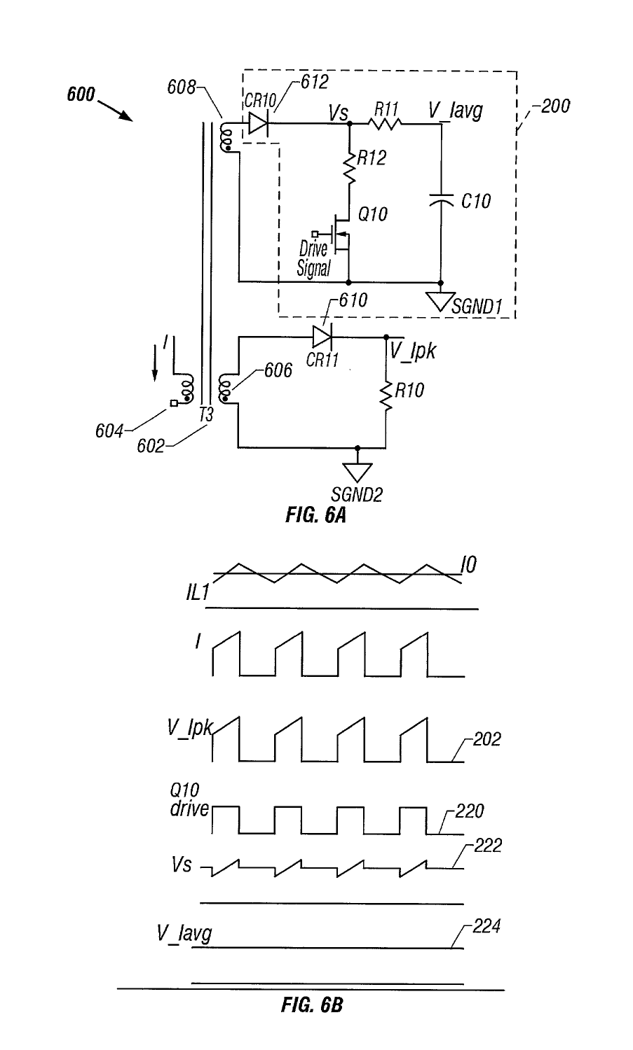

In some applications, the sensed dc output current and the peak switch current are referenced to different grounds. A dc/dc converter where peak current protection is implemented on the primary side while the current share control is implemented on the secondary side is a typical example. FIG. 6 shows the embodiment of this concept. To simplify the drawing, again, the power stage is omitted. Notice the difference of the current sensing transformer 602 from the previous embodiments. The current sensing transformer has two secondary windings, 606 and 608, one feeding diode 610 to provide a sensed peak current signal, one feeding diode 612 to provide a sensed dc output current signal. Since the current sensing transformer 602 has two secondary sides, the two signals can be referenced to different grounds SGND1 and SGND2. Selection of the circuit parameters such as resistor values can follow the guidelines described above. One can even design the current sensing transformer secondary windings differently so that the peak current signal and the average dc current signal can be flexibly scaled to the levels desired.

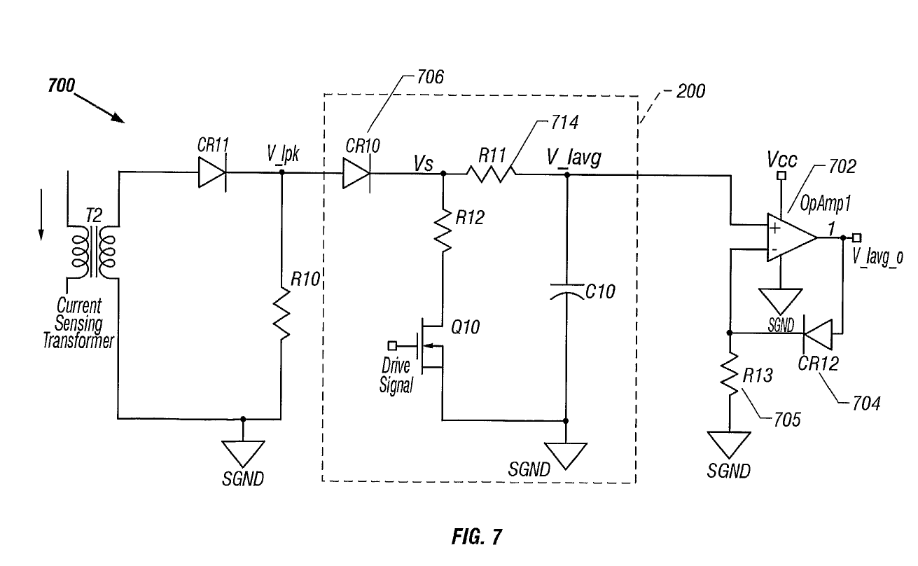

FIG. 7 shows an improvement of the embodiment presented in FIG. 5 where the sensed dc average current V_{Ivg} is one diode voltage drop below the incoming signal V_{Ipk}. Adding an op-amp 702 after the low pass filter provides a possibility to recover this voltage drop. A diode 704 is between the output and the negative input of the op-amp. By choosing the resistor 705 value to be equal to the resistor 714, the output of op-amp 702 generates a signal V_{Iavg.} which excludes the voltage drop of diode 706.

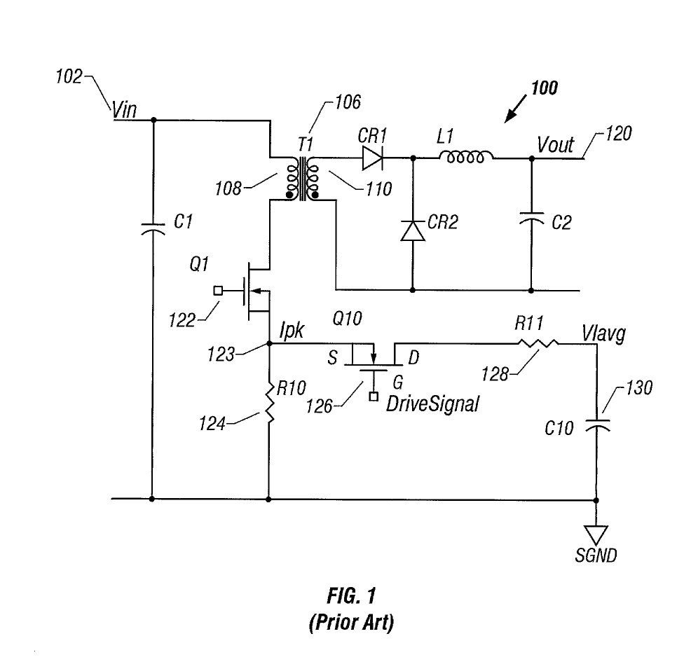

In summary, the present invention provides several benefits in addition to providing a dc current from a sensed peak current. First, the control switch is referenced to the ground, and therefore floating drive for the series switch in the prior art FIG. 1 is not necessary. Second, the peak current signal is always available regardless of the status of the control switch. By separating the peak and average current signals, the converter can be better controlled and both peak current mode control and current sharing control can be optimized. Third, referencing the peak current and average current signals to the different grounds provides freedom to implement different control schemes.

In the above embodiments, the control switch (e.g., 208 in FIG. 2) is synchronized with the in-coming peak current signal VIpk, i.e., the switch is on when the peak current signal is applied to the current estimation circuit and the switch is off when the peak current is zero. It should be pointed out that the control signal for the switch in the average current estimation circuit can be implemented in different ways, such as inverting, AND, OR or other operations of the power switch(es) control signal(s) depending on how the current sensing is implemented and the topology used.

Although the present invention has been described in detail, those skilled in the art should understand that they can make various changes, substitutions and alterations herein without departing from the spirit and scope of the invention in its broadest form. Indeed, the term “switch mode power supply” is meant to include all topologies with or without transformer isolation. Examples of such variations are implementations of the proposed current sensing scheme to different topologies, such as buck, full bridge, half bridge, or push-pull. A MOSFET is used as the control switch in the above embodiments, other types of active switch such as a bipolar junction transistor is also a viable choice. Slight modification such as exchanging the position of the control switch Q10 and the resistor R12 does not change the nature of the circuit and operation principle.

We claim:

1. An average current estimation circuit comprising:
(a) a diode;
(b) a resistor in series with a switch, with the resistor coupled to a termination of the diode;
(c) an RC filter in parallel with the resistor and switch of element (b).

2. The average current estimation circuit of claim 1 wherein the switch is synchronized with an incoming peak current signal.

3. The average current estimation circuit of claim 1 wherein an average current signal is sensed across a capacitor in the RC filter.

4. The average current estimation circuit of claim 1 wherein the RC filter smoothes an average current signal.

5. A switch mode power supply comprising:
(a) a peak current sensing circuit using a current sensing shunt; and
(b) an average current estimation circuit.

6. The switch mode power supply of claim 5 wherein a peak current signal is sensed across the current sensing shunt.

7. The switch mode power supply of claim 5 wherein the average current estimation circuit comprises:
(a) a diode;
(b) a resistor in series with a switch, with the resistor coupled to a termination of the diode;
(c) an RC filter in parallel with the resistor and switch of element (b).

8. The switch mode power supply of claim 7 wherein the switch is synchronized with an incoming peak current signal.

9. The switch mode power supply of claim 5 further comprises a power switch in series with the current sensing shunt.

10. The switch mode power supply of claim 9 wherein the switch in the average current estimation circuit is synchronized with the power switch.

11. The average current estimation circuit of claim 5 wherein an average current signal is sensed across a capacitor in the RC filter.

12. A switch mode power supply comprising:
(a) a peak current sensing circuit using a current sensing transformer; and
(b) an average current estimation circuit wherein (a) and (b) are in parallel.

13. The switch mode power supply of claim 12 wherein the peak current sensing circuit further comprises a diode and a shunt resistor in series with a secondary winding of the current sensing transformer.

14. The switch mode power supply of claim 13 wherein the peak current signal is sensed across the shunt resistor.

15. The switch mode power supply of claim 12 wherein the average current estimation circuit comprises:
(a) a diode;
(b) a resistor in series with a switch, with the resistor coupled to a termination of the diode;
(c) an RC filter in parallel with the resistor and switch of element (b).

16. The switch mode power supply of claim 15 wherein an average current signal is sensed across a capacitor of the RC filter.

17. The switch mode power supply of claim 12 wherein a switch in the average current estimation circuit is synchronized with an incoming current signal.

18. A switch mode power supply comprising:
(a) a peak current sensing circuit using a current sensing transformer;
(b) an average current sensing circuit, wherein elements (a) and (b) cascade.

19. The switch mode power supply of claim 18 wherein the peak current sensing circuit further comprises a diode and a shunt resistor in series with a secondary winding of the current sensing transformer.

20. The switch mode power supply of claim 19 wherein the peak current signal is sensed across the shunt resistor.

21. The switch mode power supply of claim 18 wherein the average current estimation circuit comprises:
(a) a diode;
(b) a resistor in series with a switch, with the resistor coupled to a termination of the diode;
(c) an RC filter in parallel with the resistor and switch of element (b).

22. The switch mode power supply of claim 18 wherein an average current signal is sensed across a capacitor of the RC filter.

23. The switch mode power supply of claim 18 wherein a switch in the average current estimation circuit is synchronized with an incoming current signal.

24. A switch mode power supply comprising:
(a) a peak current sensing circuit;
(b) an average current estimation circuit;
(c) a current sensing transformer wherein both the peak current sensing circuit and the average current estimation circuit are coupled to the current sensing transformer.

25. The switch mode power supply of claim 24 wherein the current sensing transformer has two secondary windings.

26. The switch mode power supply of claim 24 wherein a peak current signal and an average current signal can be referenced to a first and a second ground.

27. The switch mode power supply of claim 24 wherein the peak current sensing circuit further comprises a diode and a shunt resistor in series with a secondary winding of the current sensing transformer.

28. The switch mode power supply of claim 27 wherein the peak current signal is sensed across the shunt resistor.

29. The switch mode power supply of claim 24 wherein the average current estimation circuit comprises:
(a) a diode;
(b) a resistor in series with a switch, with the resistor coupled to a termination of the diode;
(c) an RC filter in parallel with the resistor and switch of element (b).

30. The switch mode power supply of claim 24 wherein an average current signal is sensed across a capacitor of the RC filter.

31. The switch mode power supply of claim 24 wherein a switch in the average current estimation circuit is synchronized with an incoming current signal.

32. A switch mode power supply comprising
(a) a peak current sensing circuit;
(b) a average current estimation circuit; and
(c) an op-amp coupled to the output of the average current sensing circuit.

33. The switch mode power supply of claim 32 wherein the op-amp is configured as a non-inverting amplifier and is coupled to a diode between the negative input of the op-amp and the output of the op-amp.

34. The switch mode power supply of claim 32 wherein a resistor from a negative input of the op-amp and the ground.

35. The switch mode power supply of claim 32 wherein the op-amp offsets a voltage drop from a diode in the average current estimation circuit.
